(19) United States
(12) Patent Application Publication
(10) Pub. No.: US 2025/0306449 A1
(43) Pub. Date: Oct. 2, 2025

(54) PELLICLE FILM, PELLICLE, AND METHOD FOR MEASURING VISIBLE LIGHT TRANSMITTANCE AND STANDARD DEVIATION OF VISIBLE LIGHT TRANSMITTANCE OF PELLICLE FILM

(71) Applicant: LINTEC Corporation, Tokyo (JP)

(72) Inventors: Shuhei KUBO, Tokyo (JP); Takahiro UEDA, Phoenix, AZ (US); Takumi FURUYA, Phoenix, AZ (US); Isao ICHIKAWA, Tokyo (JP); Jun KAWAHARA, Tokyo (JP); Yoshiaki HAGIHARA, Tokyo (JP)

(21) Appl. No.: 18/620,655

(22) Filed: Mar. 28, 2024

(51) Int. Cl. G03F 1/62; G01N 21/59; G06T 7/00

(52) U.S. Cl. CPC G03F 1/62; G01N 21/59; G06T 7/0004; G06T 2207/10152

(57) ABSTRACT

A pellicle film having a porous structure includes carbon nanotubes. The pellicle film has a first pellicle film surface and a second pellicle film surface on a side opposite to the first pellicle film surface, a visible light transmittance calculated by a numerical formula (Numerical Formula 1) below is in a range from 60% to 85%, and a standard deviation of the visible light transmittance is 0.56% or less.

T={(Tp−Td)/(Tb−Td)}×100 (Numerical Formula 1)

(In the numerical formula (Numerical Formula 1), T represents a visible light transmittance of the pellicle film, Tp represents a pixel value in the image of the pellicle film in the light-transmitting state, Tb represents a pixel value in the image of the image-capturing position in the bright state, and Td represents a pixel value in the image of the image-capturing position in the dark state.)

### TECHNICAL FIELD

The present invention relates to a pellicle film, a pellicle, and a method for measuring a visible light transmittance and a standard deviation of the visible light transmittance of a pellicle film.

### BACKGROUND ART

In a process of manufacturing a semiconductor device or the like, for example, a photoresist is applied to a substrate such as a semiconductor wafer, the substrate having the photoresist thereon is irradiated with light using a photomask, and the photoresist is removed to thereby form a desired circuit pattern on the substrate.

If light is applied in a state where foreign matter adheres to the photomask, the adhering foreign matter may adversely affect the circuit pattern formed on the substrate. Therefore, in order to suppress adhesion of foreign matter to the photomask, a pellicle that includes a pellicle film for capturing foreign matter is used in some cases. The pellicle is disposed above the photomask at a distance such that the pellicle film is not in contact with the photomask.

In recent years, use of extreme ultra violet (EUV) has been studied in order to form a finer circuit pattern. EUV means light with a wavelength in a range from 1 nm to 100 nm. For example, specifically, a light beam with a wavelength of about 13.5 nm±0.3 nm is being used as EUV. When a pellicle film is irradiated with EUV, although the EUV is transmitted through the pellicle film, a part of the radiated EUV is absorbed by the pellicle film. The light energy of absorbed EUV is converted into thermal energy, and the temperature of the pellicle film is thereby increased. Thus, the pellicle film is required to have, for example, transparency to EUV, heat resistance, and durability.

In a pellicle used in a step of forming a circuit pattern using EUV, carbon nanotubes have been studied as one of the materials used for a pellicle film included in the pellicle.

For example, Patent Literature 1 (JP No. 2023-106455 A) discloses a pellicle film for exposure, the pellicle film including a carbon nanotube film containing carbon nanotubes. In the carbon nanotube film disclosed in Patent Literature 1, the transmittance of EUV light at a wavelength of 13.5 nm is 80% or more, the thickness is in a range from 1 nm to 50 nm, and 30 of a reflectance is 15% or less.

As a technique for evaluating uniformity of the EUV transmittance in the pellicle film including carbon nanotubes and disclosed in Patent Literature 1, a reflectance measured with a reflection spectroscopic film thickness meter is employed. The pellicle film disclosed in Patent Literature 1 has enhanced uniformity of the EUV transmittance because of enhancement of uniformity of the thickness of the pellicle film. However, the numerical value measured with a reflection spectroscopic film thickness meter merely indirectly evaluates uniformity of the EUV transmittance and does not directly evaluate variation in the transmittance of light that is transmitted through the pellicle film. Therefore, there is a concern that the pellicle film disclosed in Patent Literature 1 does not actually have sufficiently enhanced uniformity of the EUV transmittance. If uniformity of the EUV transmittance of the pellicle film is not sufficiently enhanced, the pellicle film is likely to be deformed, and consequently, the mechanical strength tends to decrease. Thus, further improvements have been required for the pellicle film.

### SUMMARY OF THE INVENTION

An object of the invention is to provide a pellicle film including carbon nanotubes, in which variation in EUV transmittance is reduced and which has a small amount of deformation, while high transparency to EUV is ensured, and a pellicle including the pellicle film. Another object of the invention is to provide a method for measuring a visible light transmittance and a standard deviation of the visible light transmittance of a pellicle film, which can be used as an indicator of essential variation in EUV transparency of the pellicle film.

[1] A pellicle film having a porous structure,
in which the pellicle film includes carbon nanotubes,
the pellicle film has a first pellicle film surface and a second pellicle film surface on a side opposite to the first pellicle film surface,
a visible light transmittance is in a range from 60% to 85%, the visible light transmittance being calculated by a numerical formula (Numerical Formula 1) below based on:
(1) an image of the pellicle film in a light-transmitting state, the image being composed of 700,000 pixels or more in an area of 14,300 mm² and captured on a side of the first pellicle film surface in a state where a side of the second pellicle film surface is placed on an image-capturing position and white light with a wavelength in a range from 400 nm to 750 nm is applied from the side of the second pellicle film surface,
(2) an image of the image-capturing position in a bright state, the image being composed of the same number of pixels or more as that in (1) above in the area and obtained by imaging the image-capturing position not including the pellicle film in a state where the white light is applied, and
(3) an image of the image-capturing position in a dark state, the image being composed of the same number of pixels or more as that in (1) above in the area and obtained by imaging the image-capturing position not including the pellicle film in a light-shielded state, and
a standard deviation of the visible light transmittance is 0.56% or less,

$$T = \{ ( Tp - Td ) / ( Tb - Td ) \} \times 100 \qquad ( Numerical Formula 1 )$$

in the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

[2] The pellicle film according to [1],
in which a coefficient of variation of the visible light transmittance is 0.68 or less.

[3] The pellicle film according to [1] or [2],
in which the carbon nanotubes have a length in a range from 0.1 μm to 1,000 μm.

[4] The pellicle film according to any one of [1] to [3],
in which the carbon nanotubes have a cross-sectional diameter in a range from 0.2 nm to 50 nm.

[5] The pellicle film according to any one of [1] to [4],
being a free-standing pellicle film.

[6] A pellicle including:
the pellicle film according to any one of [1] to [5]; and
a support that has a frame and an opening surrounded by the frame and that supports the pellicle film.

[7] A method for measuring a visible light transmittance and a standard deviation of the visible light transmittance of a pellicle film having a porous structure, the method including:
preparing a pellicle film including carbon nanotubes and having a first pellicle film surface and a second pellicle film surface on a side opposite to the first pellicle film surface;
placing the prepared pellicle film on an image-capturing position such that the second pellicle film surface faces the image-capturing position;
applying white light with a wavelength in a range from 400 nm to 750 nm from a side of the second pellicle film surface of the placed pellicle film to transmit the white light through the pellicle film;
capturing an image with an image-capturing device, in a state where the white light is applied, on a side of the first pellicle film surface to which the white light is not applied, thereby acquiring an image of the pellicle film in a light-transmitting state, the image being composed of 700,000 pixels or more in an area of 14,300 mm²;
capturing an image of the image-capturing position not including the pellicle film in a state where the white light is applied, thereby acquiring an image of the image-capturing position in a bright state, the image being composed of 700,000 pixels or more in an area of 14,300 mm²;
capturing an image of the image-capturing position not including the pellicle film in a light-shielded state where the white light is not applied, thereby acquiring an image of the image-capturing position in a dark state, the image being composed of 700,000 pixels or more in an area of 14,300 mm²; and
calculating a visible light transmittance and a standard deviation of the visible light transmittance of the pellicle film based on the image of the pellicle film in the light-transmitting state, the image of the image-capturing position in the bright state, and the image of the image-capturing position in the dark state,
in which the visible light transmittance of the pellicle film is determined by a numerical formula (Numerical Formula 1) below:

$$T = \{ ( Tp - Td ) / ( Tb - Td ) \} \times 100 \qquad ( Numerical Formula 1 )$$

in the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

An aspect of the invention can provide a pellicle film including carbon nanotubes, in which variation in EUV transparency is reduced and which has a small amount of deformation, while high transparency to EUV is ensured and a pellicle including the pellicle film. Another aspect of the invention can provide a method for measuring a visible light transmittance and a standard deviation of the visible light transmittance of a pellicle film, which can be used as an indicator of essential variation in EUV transparency of the pellicle film.

### BRIEF DESCRIPTION OF DRAWINGS

FIG. 1 is a schematic sectional view illustrating an example of a pellicle film according to an exemplary embodiment of the invention.

FIG. 2A is a schematic explanatory view illustrating an example of a method for measuring a visible light transmittance and a standard deviation of the visible light transmittance of a pellicle film according to the exemplary embodiment.

FIG. 2B is a schematic explanatory view illustrating an example of a method for measuring a visible light transmittance and a standard deviation of the visible light transmittance of a pellicle film according to the exemplary embodiment.

FIG. 2C is a schematic explanatory view illustrating an example of a method for measuring a visible light transmittance and a standard deviation of the visible light transmittance of a pellicle film according to the exemplary embodiment.

FIG. 3 is a schematic plan view illustrating an example of a pellicle according to the exemplary embodiment.

FIG. 4 is a sectional view taken along line IV-IV in FIG. 3.

### DETAILED DESCRIPTION

Hereinafter, a pellicle film, a pellicle, and a method for measuring a visible light transmittance and a standard deviation of the visible light transmittance of a pellicle film according to preferred exemplary embodiments of the invention will be described.

### Pellicle Film

A pellicle film according to the exemplary embodiment is a pellicle film having a porous structure. The pellicle film includes carbon nanotubes. The pellicle film has a first pellicle film surface and a second pellicle film surface on a side opposite to the first pellicle film surface. The pellicle film has a visible light transmittance in a range from 60% to 85%, the visible light transmittance being calculated by a numerical formula (Numerical Formula 1) below based on (1) an image of the pellicle film in a light-transmitting state, the image being composed of 700,000 pixels or more in an area of 14,300 mm² and captured on a side of the first pellicle film surface in a state where a side of the second pellicle film surface is placed on an image-capturing position and white light with a wavelength in a range from 400 nm to 750 nm is applied from the side of the second pellicle film surface, (2) an image of the image-capturing position in a bright state, the image being composed of the same number of pixels or more as that in (1) above in the area and obtained by imaging the image-capturing position not including the pellicle film in a state where the white light is applied, and (3) an image of the image-capturing position in a dark state, the image being composed of the same number of pixels or more as that in (1) above in the area and obtained by imaging the image-capturing position not including the pellicle film in a light-shielded state, and a standard deviation of the visible light transmittance of 0.56% or less.

$$T = \{ ( Tp - Td ) / ( Tb - Td ) \} \times 100 \qquad ( Numerical Formula 1 )$$

In the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

Since the pellicle film according to the exemplary embodiment has the above configuration, variation in EUV transparency is reduced and the amount of deformation is small, while high transparency to EUV is ensured. Specifically, in the pellicle film according to the exemplary embodiment, the visible light transmittance calculated by the numerical formula (Numerical Formula 1) is 60% or more, and thus the EUV transmittance can be adjusted to 93% or more.

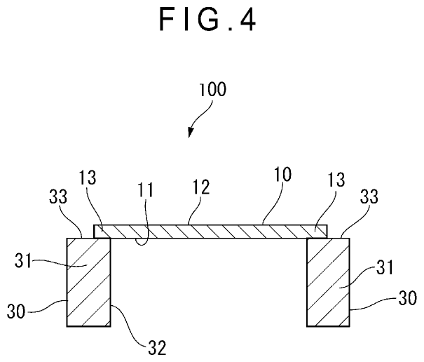

It is known that, in a pellicle film including carbon nanotubes (CNTs), there is a correlation between a light transmittance at a wavelength of 13.5 nm and a light transmittance at a wavelength of 550 nm (refer to, for example, Marina, Y, et al., “CNT EUV pellicle tunability and performance in a scanner-like environment”, Proc. SPIE 11609, Extreme Ultraviolet (EUV) Lithography XII, 116090Y, (23 Mar. 2021), FIG. 4(a); doi: 10.1117/12.2584519). The inventors of the invention have found that when the visible light transmittance of a pellicle film is 60% or more, the EUV transmittance can be adjusted to 93% or more, and when the visible light transmittance is 80% or more, the EUV transmittance can be adjusted to 95% or more.

The visible light transmittance of a pellicle film has a correlation with the thickness of the pellicle film. The smaller the thickness of the pellicle film, the higher the visible light transmittance. On the other hand, as the thickness of the pellicle film decreases, the pellicle film is likely to be deformed or ruptured.

When the visible light transmittance is 85% or less, the pellicle film is considered to have a certain degree of thickness, and thus the amount of deformation of the pellicle film is reduced. As a result, the mechanical strength of the pellicle film is ensured. Moreover, in the pellicle film according to the exemplary embodiment, since the standard deviation of the visible light transmittance calculated by the numerical formula (Numerical Formula 1) is 0.56% or less, a light beam is considered to be nearly uniformly transmitted at least over the entire surface of the pellicle film in a region where the visible light transmittance is measured. As a result, variation in EUV transparency of the pellicle film is reduced. Furthermore, the fact that visible light is nearly uniformly transmitted at least over the entire surface of the pellicle film in a region where the visible light transmittance is measured is considered to mean that the pellicle film has a nearly uniform thickness over the entire surface. Thus, the pellicle film according to the exemplary embodiment has, in the visible light transmittance calculated by the numerical formula (Numerical Formula 1), a standard deviation of the visible light transmittance of 0.56% or less; therefore, it is considered that the amount of deformation of the pellicle film can be reduced compared with a pellicle film that has substantially the same visible light transmittance and a standard deviation of the visible light transmittance of more than 0.56%.

The fact that the visible light transmittance of the pellicle film according to the exemplary embodiment is a numerical value measured based on (1), (2), and (3) above and the standard deviation of the visible light transmittance is small means that essential variation in the transmittance of the pellicle film is small. That is, according to a method for measuring a visible light transmittance and a standard deviation of the visible light transmittance of a pellicle film according to the exemplary embodiment described later, not a numerical value obtained by reflection measurement but a visible light transmittance can be directly evaluated and thus can be used as an indicator of essential variation in EUV transparency of the pellicle film.

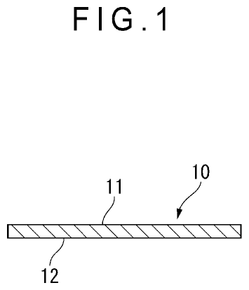

Referring to FIG. 1, FIG. 1 schematically illustrates a cross section of a pellicle film according to the exemplary embodiment. A pellicle film 10 has a porous structure and includes carbon nanotubes. The pellicle film 10 has a first pellicle film surface 11 and a second pellicle film surface 12 on a side opposite to the first pellicle film surface 11. A visible light transmittance of the pellicle film 10 and a standard deviation of the visible light transmittance satisfy the specific numerical ranges described above. The visible light transmittance is calculated by the numerical formula (Numerical Formula 1) based on an image of the pellicle film 10 in the light-transmitting state according to (1) above, the image being captured on the first pellicle film surface 11 in a state where white light with a wavelength in a range from 400 nm to 750 nm is applied from a side of the second pellicle film surface 12, an image of the image-capturing position in the bright state according to (2) above, the image-capturing position not including the pellicle film 10, and an image of the image-capturing position in the dark state according to (3) above, the image-capturing position not including the pellicle film 10.

Herein, for convenience, the terms “first pellicle film surface” and “second pellicle film surface” of the pellicle film are used in order to clarify the positional relationship between a surface to be placed on the image-capturing position and a surface to be imaged and, in a pellicle described later, the positional relationship between a surface facing a supporting surface of a support and its opposite surface. Therefore, in some cases, both the first pellicle film surface and the second pellicle film surface can be interchangeably used, and the first pellicle film surface and the second pellicle film surface can be used without distinction.

An example of the pellicle film according to the exemplary embodiment has been described above with reference to FIG. 1. The pellicle film according to the exemplary embodiment is not limited thereto. The pellicle film according to the exemplary embodiment may employ any of various forms as long as the above-described advantages are obtained.

The carbon nanotubes included in the pellicle film according to the exemplary embodiment are not particularly limited and are preferably at least one selected from the group consisting of multi-walled carbon nanotubes (MWCNT), few-walled carbon nanotubes (FWCNT), double-walled carbon nanotubes (DWCNT), and single-walled carbon nanotubes (SWCNT).

The carbon nanotubes are obtained by a publicly known production method such as an arc discharge method, a laser ablation method, or chemical vapor deposition.

The length of the carbon nanotubes is preferably, for example, in a range from 0.1 μm to 1,000 μm.

The length of the carbon nanotubes is more preferably 0.5 μm or more, still more preferably 1 μm or more.

The length of the carbon nanotubes is more preferably 600 μm or less, still more preferably 400 μm or less.

The cross-sectional diameter of the carbon nanotubes is preferably in a range from 0.2 nm to 50 nm.

The cross-sectional diameter of the carbon nanotubes is more preferably 0.5 nm or more, still more preferably 1 nm or more.

The cross-sectional diameter of the carbon nanotubes is more preferably 30 nm or less, still more preferably 20 nm or less.

Herein, the cross-sectional diameter may be simply referred to as a diameter.

The pellicle film according to the exemplary embodiment has a visible light transmittance in a range from 60% to 85% as calculated by the numerical formula (Numerical Formula 1). From the viewpoint of EUV transparency of the pellicle film, the visible light transmittance calculated by the numerical formula (Numerical Formula 1) is preferably 65% or more, more preferably 70% or more, still more preferably 75% or more, and still further more preferably 80% or more. From the viewpoint of reducing the amount of deformation of the pellicle film, the visible light transmittance calculated by the numerical formula (Numerical Formula 1) is preferably 85% or less, more preferably 84% or less, and still more preferably 83.5% or less. The visible light transmittance calculated by the numerical formula (Numerical Formula 1) is an average value of the visible light transmittance. Herein, the average value of the visible light transmittance refers to an average value of the visible light transmittance over the entire surface of the pellicle film in a region where the visible light transmittance is measured.

The pellicle film according to the exemplary embodiment has, in the visible light transmittance calculated by the numerical formula (Numerical Formula 1), a standard deviation of the visible light transmittance of 0.56% or less. From the viewpoint that variation in EUV transparency of the pellicle film is more likely to be reduced and deformation of the pellicle film is more likely to be reduced, the standard deviation of the visible light transmittance is preferably 0.55% or less, more preferably 0.545% or less, and still more preferably 0.54% or less.

The lower limit of the standard deviation of the visible light transmittance is preferably close to 0%, and may be, for example, more than 0% or may be 0.1% or more.

The standard deviation of the visible light transmittance is a numerical value calculated based on the visible light transmittance calculated by the numerical formula (Numerical Formula 1).

From the viewpoint that variation in EUV transparency of the pellicle film is more likely to be reduced and deformation of the pellicle film is more likely to be reduced, the pellicle film according to the exemplary embodiment preferably has, in the visible light transmittance calculated by the numerical formula (Numerical Formula 1), a coefficient of variation of the visible light transmittance of 0.7 or less, more preferably 0.68 or less, and still more preferably 0.65 or less.

The lower limit of the coefficient of variation of the visible light transmittance is preferably close to 0, and may be, for example, more than 0 or may be 0.1 or more.

Herein, the coefficient of variation of the visible light transmittance is a numerical value calculated based on the visible light transmittance calculated by the numerical formula (Numerical Formula 1) and the above-described standard deviation of the visible light transmittance. The coefficient of variation is determined by dividing the standard deviation of the visible light transmittance by the visible light transmittance (that is, the average value of the visible light transmittance).

### Method for Measuring Visible Light Transmittance and Standard Deviation of Visible Light Transmittance of Pellicle Film

A method for measuring a visible light transmittance and a standard deviation of the visible light transmittance of a pellicle film having a porous structure according to the exemplary embodiment includes the following step (S1) to step (S7). The visible light transmittance of the pellicle film is determined by a numerical formula (Numerical Formula 1) below in step (S7). Use of a measurement method described below as the method for measuring a visible light transmittance and a standard deviation of the visible light transmittance of a pellicle film enables direct evaluation of the visible light transmittance, enables variation in the visible light transmittance to be directly evaluated, and thus can provide an indicator of essential variation in EUV transparency of the pellicle film.

Step (S1): a step of preparing a pellicle film including carbon nanotubes and having a first pellicle film surface and a second pellicle film surface on a side opposite to the first pellicle film surface.

Step (S2): a step of placing the prepared pellicle film on an image-capturing position such that the second pellicle film surface faces the image-capturing position.

Step (S3): a step of applying white light with a wavelength in a range from 400 nm to 750 nm from a side of the second pellicle film surface of the placed pellicle film to transmit the white light through the pellicle film.

Step (S4): a step of capturing an image with an image-capturing device, in a state where the white light is applied, on a side of the first pellicle film surface to which the white light is not applied, thereby acquiring an image of the pellicle film in a light-transmitting state, the image being composed of 700,000 pixels or more in an area of 14,300 mm².

Step (S5): a step of capturing an image of the image-capturing position not including the pellicle film in a state where the white light is applied, thereby acquiring an image of the image-capturing position in a bright state, the image being composed of 700,000 pixels or more in an area of 14,300 mm².

Step (S6): a step of capturing an image of the image-capturing position not including the pellicle film in a light-shielded state where the white light is not applied, thereby acquiring an image of the image-capturing position in a dark state, the image being composed of 700,000 pixels or more in an area of 14,300 mm².

Step (S7): a step of calculating a visible light transmittance and a standard deviation of the visible light transmittance of the pellicle film based on the image of the pellicle film in the light-transmitting state, the image of the image-capturing position in the bright state, and the image of the image-capturing position in the dark state.

The visible light transmittance of the pellicle film is determined by a numerical formula (Numerical Formula 1) below.

$$T = \{ ( Tp - Td ) / ( Tb - Td ) \} \times 100 \qquad ( Numerical Formula 1 )$$

In the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

The image of the pellicle film in the light-transmitting state according to (1) above is preferably an image obtained by the operations of steps (S3) and (S4) above. The image of the image-capturing position in the bright state according to (2) above is preferably an image obtained by the operation of step (S5) above. The image of the image-capturing position in the dark state according to (3) above is preferably an image obtained by the operation of step (S6) above.

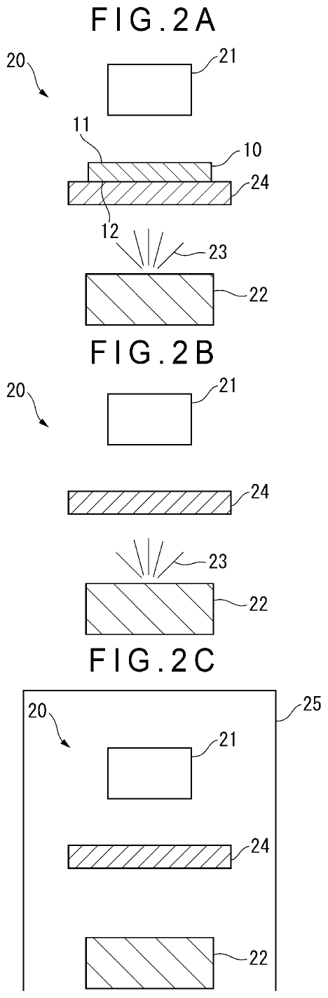

The method for measuring a visible light transmittance and a standard deviation of the visible light transmittance of a pellicle film according to the exemplary embodiment will be described below with reference to the drawings. FIGS. 2A, 2B, and 2C are each a schematic explanatory view illustrating a method for measuring a visible light transmittance and a standard deviation of the visible light transmittance of a pellicle film according to the exemplary embodiment.

The visible light transmittance and the standard deviation of the visible light transmittance of the pellicle film according to the exemplary embodiment can be measured with, for example, a visible light transmittance measuring device 20 illustrated in FIGS. 2A, 2B, and 2C. FIGS. 2A, 2B, and 2C are sectional views of the visible light transmittance measuring device 20. As illustrated in FIGS. 2A, 2B, and 2C, the visible light transmittance measuring device 20 include a camera 21 (an example of the image-capturing device), an irradiation unit 22 having a light source (not illustrated) that can emit white light 23, and a table 24 (an example of the image-capturing position) on which the pellicle film 10 can be placed. In the visible light transmittance measuring device 20, the light source (not illustrated) included in the irradiation unit 22 is a while light emitting diode (LED) light source. The camera 21 is not particularly limited as long as the camera 21 can capture an image composed of 700,000 pixels or more described later. The gap between the camera 21 and the table 24 is not particularly limited as long as an image composed of 700,000 pixels or more in an area of 14,300 mm² described later can be captured. The camera 21 may be, for example, a digital camera such as a digital single-lens reflex camera.

In step (S1), first, a pellicle film having a porous structure according to the exemplary embodiment is prepared. The pellicle film prepared in step (S1) may be specifically, for example, a pellicle film obtained by a preferred method for producing a pellicle film described later. In step (S1), the pellicle film 10 illustrated in FIG. 1 is prepared as illustrated in FIG. 2A.

In step (S2), the pellicle film prepared in step (S1) is placed on an image-capturing position. In step (S2), the pellicle film 10 is placed on the table 24 such that the second pellicle film surface 12 faces the table 24, as illustrated in FIG. 2A. The table 24 is formed of a transparent material having high translucency, such as glass, at least over the entire surface in a region where the pellicle film 10 is placed. Note that the pellicle film 10 may be placed such that the first pellicle film surface 11 faces the table 24 instead of being placed such that the second pellicle film surface 12 faces the table 24. In this case, an image of the pellicle film 10 is captured by the camera 21 from a side of the second pellicle film surface 12 in step (S4) described later.

In step (S3), white light is applied from a side of the surface on which the pellicle film is placed on the image-capturing position to transmit the white light through the pellicle film. The wavelength of the white light is in a range from 400 nm to 750 nm. As illustrated in FIG. 2A, the white light 23 with a wavelength in a range from 400 nm to 750 nm emitted from the light source (not illustrated) included inside the irradiation unit 22 is radiated toward the table 24. When the white light 23 is radiated toward the table 24, the white light 23 is transmitted through the table 24. As the white light 23 is transmitted through the table 24, the pellicle film 10 placed on the table 24 is irradiated with the white light 23. The white light 23 that illuminates the pellicle film 10 illuminates the second pellicle film surface 12 of the pellicle film 10. When the white light 23 is radiated from the second pellicle film surface 12 of the pellicle film 10, the white light 23 is transmitted through the pellicle film 10. At this time, the pellicle film 10 is in a light-transmitting state.

In step (S4), an image is captured with an image-capturing device, in a state where the white light is applied, on the surface side to which the white light is not applied, thereby acquiring an image of the pellicle film in the light-transmitting state. As illustrated in FIG. 2A, an image of the pellicle film 10 in the light-transmitting state is captured by the camera 21 from a side of the first pellicle film surface 11, which is not irradiated with the white light 23, in a state where the white light 23 is still radiated from a side of the second pellicle film surface 12. Thus, the captured image of the surface of the pellicle film 10 is acquired. The captured image is an image that has an area of 14,300 mm² and is composed of 700,000 pixels or more. The pixel value of the acquired image is a pixel value Tp indicating that the white light 23 is transmitted in the captured image of the pellicle film 10 in the light-transmitting state, as expressed by the numerical formula (Numerical Formula 1).

In step (S5), an image of the image-capturing position not including the pellicle film is captured in a state where the white light is applied, thereby acquiring an image of the image-capturing position in the bright state. As illustrated in FIG. 2B, while the white light 23 is still applied, the pellicle film 10 is removed from the table 24, and an image of the table 24 is then captured by the camera 21. Thus, a captured image of the table 24 in the bright state is acquired. The captured image of the table 24 does not include the pellicle film 10. The captured image is an image that has an area of 14,300 mm² and is composed of 700,000 pixels or more. The pixel value of the acquired image is a pixel value Tb indicating that the white light 23 is transmitted in the captured image of the table 24, which is an example of the image-capturing position, in the bright state, as expressed by the numerical formula (Numerical Formula 1). The pixel value Tb serves as the maximum value of the visible light transmittance.

In step (S6), an image of the image-capturing position not including the pellicle film is captured in the light-shielded state where irradiation of the white light is stopped, thereby acquiring an image of the image-capturing position in the dark state. As illustrated in FIG. 2C, the power supply of the irradiation unit 22 is turned off to stop the irradiation of the white light 23. A light-shielding member 25 that shields light is used so that almost no light enters a space where the image of the table 24 is captured. The light-shielding member 25 may be, for example, a blackout curtain. In this state, an image of the table 24 is captured by the camera 21. Thus, a captured image of the table 24 in the dark state is acquired. The captured image of the table 24 does not include the pellicle film 10. The captured image is an image that has an area of 14,300 mm² and is composed of 700,000 pixels or more. The pixel value of the acquired image is a pixel value Td determined when the white light 23 is not applied in the captured image of the table 24, which is an example of the image-capturing position, in the dark state, as expressed by the numerical formula (Numerical Formula 1). The pixel value Td serves as the minimum value of the visible light transmittance.

In step (S7), the visible light transmittance and the standard deviation of the visible light transmittance of the pellicle film are calculated based on the images acquired in steps (S4), (S5), and (S6). The visible light transmittance and the standard deviation of the visible light transmittance are calculated based on the acquired images by a numerical formula (Numerical Formula 1) below using, for example, an information processing unit (not illustrated) constituted by, for example, a computer such as a personal computer or a server that is electrically connected to the visible light transmittance measuring device 20. At this time, the coefficient of variation of the visible light transmittance can also be calculated.

$$T = \{ ( Tp - Td ) / ( Tb - Td ) \} \times 100 \qquad ( Numerical Formula 1 )$$

In the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

The pixel value Tb is a pixel value of the image of the image-capturing position in the bright state in which the pellicle film 10 is not included, and the pixel value Td is a pixel value of the image of the image-capturing position in the dark state in which the pellicle film 10 is not included. Accordingly, the visible light transmittance T of the pellicle film determined according to the numerical formula (Numerical Formula 1) corresponds to representing a visible light transmittance in the case where the visible light transmittance in an image of the image-capturing position not including the pellicle film 10 in the bright state is defined as 100%.

In step (S7), in the calculations of the visible light transmittance and the standard deviation of the visible light transmittance of the pellicle film, a transmittance map of the pellicle film is prepared based on the images acquired in steps (S4), (S5), and (S6). The visible light transmittance (that is, the average value of the visible light transmittance) and the standard deviation of the visible light transmittance are determined based on the prepared transmittance map of the pellicle film.

In the pellicle film according to the exemplary embodiment, the visible light transmittance of the pellicle film measured by the operation method described above is in a range from 60% to 85%, and the standard deviation of the visible light transmittance is 0.56% or less.

The pellicle film according to the exemplary embodiment may have any thickness as long as the visible light transmittance calculated by the numerical formula (Numerical Formula 1) is in a range from 60% to 85% and the standard deviation of the visible light transmittance satisfies a range of 0.56% or less. When the standard deviation of the visible light transmittance of the pellicle film according to the exemplary embodiment satisfies a range of 0.56% or less, uniformity of the thickness is consequently also increased in the region of the pellicle film where visible light is transmitted.

As described above, when the visible light transmittance of the pellicle film according to the exemplary embodiment is 60% or more, the EUV transmittance can be adjusted to 93% or more. In an example of the pellicle film according to the exemplary embodiment, when the visible light transmittance satisfies, for example, about 80%, the maximum value of the thickness of the pellicle film is, for example, 70 nm or less. In an example of the pellicle film according to the exemplary embodiment, when the visible light transmittance satisfies, for example, about 80%, the average value of the thickness of the pellicle film is, for example, 50 nm or less. In an example of the pellicle film according to the exemplary embodiment, when the visible light transmittance is 70.8%, the average value of the thickness of the pellicle film is about 47 nm. The thickness of the pellicle film according to the exemplary embodiment can be measured with a scanning probe microscope. The thickness of the pellicle film according to the exemplary embodiment is not particularly limited as long as the visible light transmittance is in a range from 60% to 85% and the standard deviation of the visible light transmittance satisfies a range of 0.56% or less. The thickness of the pellicle film according to the exemplary embodiment may be, for example, 30 nm or more in terms of average value or 35 nm or more in terms of average value. The thickness of the pellicle film according to the exemplary embodiment may be, for example, 100 nm or less in terms of average value.

The weight of the pellicle film per unit area is not particularly limited and is preferably in a range from 0.1 μg/cm² to 20 μg/cm². The weight of the pellicle film per unit area is more preferably 0.5 μg/cm² or more, still more preferably 1 μg/cm² or more. The weight of the pellicle film per unit area is more preferably 15 μg/cm² or less, still more preferably 10 μg/cm² or less. When the weight of the pellicle film per unit area is, for example, in a range from 0.1 μg/cm² to 20 μg/cm², in the pellicle film, high transparency to EUV is likely to be ensured, variation in EUV transparency is likely to be reduced, and the amount of deformation is likely to be reduced.

The pellicle film according to the exemplary embodiment is preferably a porous structure in which carbon nanotubes are deposited. Such a porous structure in which carbon nanotubes are deposited can be produced by an example of a preferred method for producing a pellicle film described later. In the pellicle film formed of such a porous structure in which carbon nanotubes are deposited, high transparency to EUV is likely to be ensured, variation in EUV transparency is likely to be reduced, and the amount of deformation is likely to be reduced.

From the viewpoint of improving transparency to exposure light, the pellicle film according to the exemplary embodiment is preferably free-standing. The phrase “a pellicle film is free-standing” means a pellicle film that is free-standing on its own and means that the pellicle film is a film having a self-supporting property (also referred to as a free-standing film). That is, a free-standing pellicle film is a pellicle film that can retain its shape by itself even in the absence of a substrate or the like.

No particular limitation is imposed on a method for adjusting a pellicle film to have a visible light transmittance in a range from 60% to 85%, calculated by the numerical formula (Numerical Formula 1), and a standard deviation of the visible light transmittance of 0.56% or less. The method may be, for example, a method for adjusting dispersion conditions for dispersing carbon nanotubes, centrifugal separation conditions for subjecting a dispersion liquid of carbon nanotubes to centrifugal separation, and other conditions in an example of a preferred method for producing a pellicle film described later.

### Method for Producing Pellicle Film

The method for producing a pellicle film according to the exemplary embodiment is not particularly limited as long as the visible light transmittance calculated by the numerical formula (Numerical Formula 1) and the standard deviation of the visible light transmittance can satisfy the above-described numerical ranges, and various production methods can be employed. Examples of the method for producing a pellicle film according to the exemplary embodiment include a filtration method (a method in which a carbon nanotube dispersion liquid is filtered through a filter, and the resulting carbon nanotube film is then peeled off from the filter to obtain a pellicle film), an application method (a method in which a carbon nanotube dispersion liquid is applied onto a substrate, and the resulting carbon nanotube film is then peeled off from the substrate to obtain a pellicle film), and an etching method (a method in which a carbon nanotube film is formed on a wafer, and the wafer is then etched to obtain a pellicle film).

As described above, the method for producing a pellicle film according to the exemplary embodiment is not particularly limited. An example of a preferred method for producing a pellicle film according to the exemplary embodiment may be, for example, a production method including the following steps.

An example of a preferred method for producing a pellicle film according to the exemplary embodiment includes step (P1) of dispersing carbon nanotubes to obtain a first dispersion liquid of carbon nanotubes, step (P2) of dispersing the first dispersion liquid by centrifugal separation to separate aggregates of carbon nanotubes, subsequently collecting the supernatant to obtain a second dispersion liquid of carbon nanotubes, step (P3) of precipitating and depositing the second dispersion liquid of carbon nanotubes on an air-permeable member to obtain a film product of carbon nanotubes formed in the form of a mat on the air-permeable member, and step (P4) of removing the air-permeable member from the film product of carbon nanotubes to obtain a pellicle film.

First, in step (P1), carbon nanotubes are dispersed in a liquid serving as a dispersion medium to prepare a first dispersion liquid of carbon nanotubes in which the carbon nanotubes are dispersed in the liquid. The liquid may be a liquid containing water. The first dispersion liquid of carbon nanotubes may contain only carbon nanotubes as a dispersoid. The carbon nanotube dispersion liquid may contain, in addition to carbon nanotubes, various additives such as a dispersing agent for dispersing carbon nanotubes. In step (P1), the method for preparing the first dispersion liquid is not particularly limited. The first dispersion liquid can be prepared using various dispersing devices. The first dispersion liquid may be prepared, for example, using a wet pulverization and dispersion device. In preparation of the first dispersion liquid using a wet pulverization and dispersion device, conditions for dispersion treatment using the wet pulverization and dispersion device may be, for example, dispersion conditions in which the pressure is in a range from 50 MPa to 200 MPa and the number of times of treatment is in a range from 1 to 10.

The weight of the carbon nanotubes per unit area may be, for example, in a range from 0.1 μg/cm² to 20 μg/cm² in terms of amount of carbon nanotubes included in the film product of carbon nanotubes prepared in step (P3).

Next, in step (P2), the first dispersion liquid of carbon nanotubes prepared in step (P1) is subjected to centrifugal separation with a centrifugal separator to separate aggregates of carbon nanotubes. Subsequently, the supernatant after centrifugal separation is collected to obtain a second dispersion liquid of carbon nanotubes. The supernatant includes carbon nanotubes. The conditions for centrifugal separation are not particularly limited. From the viewpoint of separating aggregates of carbon nanotubes, the conditions for centrifugal separation include, for example, a relative centrifugal acceleration of 100 kG or more and a treatment time of one hour or more.

Next, in step (P3), the supernatant, which is a second dispersion liquid collected in step (P2), is precipitated and deposited on an air-permeable member. For example, the supernatant collected in step (P2) is filtered through a filtration membrane serving as an air-permeable member to precipitate and deposit carbon nanotubes, thereby forming a film product of carbon nanotubes formed in the form of a mat on the filtration membrane. The filtration membrane is, for example, a filtration membrane made of nonwoven fabric. Specifically, for example, a filtration membrane made of nonwoven fabric, such as a membrane filter, is preferably used.

Subsequently, in step (P4), the filtration membrane is removed from the film product of carbon nanotubes formed in the form of a mat to obtain a pellicle film including carbon nanotubes. Before the filtration membrane is removed from the film product of fibers formed in the form of a mat or after the filtration membrane is removed from the film product of fibers formed in the form of a mat, a drying step may be performed, as needed. As needed, both a drying step and an annealing step may be performed or only an annealing step may be performed without performing a drying step.

The pellicle film obtained through step (P1) to step (P4) described above is a free-standing film.

### Pellicle

A pellicle according to the exemplary embodiment includes the pellicle film according to the exemplary embodiment described above and a support that has a frame and an opening surrounded by the frame and that supports the pellicle film.

The pellicle according to the exemplary embodiment will be described below with reference to the drawings.

Note that, in drawings for description with reference to the drawings herein, some portions are illustrated in enlarged or reduced size for simplicity of explanation.

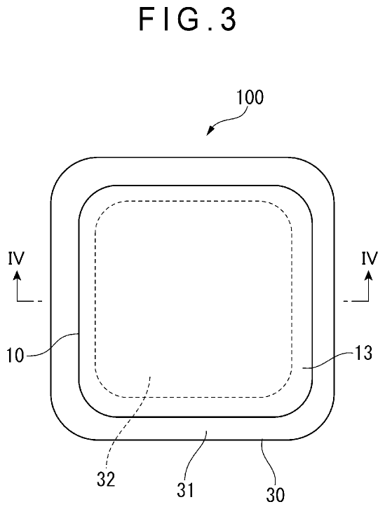

FIG. 3 is a plan view of a pellicle 100 when viewed from a surface on which a pellicle film 10 is disposed, and FIG. 4 is a sectional view of the pellicle 100 illustrated in FIG. 3. The pellicle 100 includes the pellicle film 10 and a support 30 that supports the pellicle film 10. The support 30 has a frame 31 and an opening 32 surrounded by the frame 31. The opening 32 extends from one surface of the support 30 toward the other surface of the support 30. The frame 31 and the opening 32 are each formed in a rectangular shape, and four corners of the contour of the frame 31 are rounded. The frame 31 has a supporting surface 33 that faces the pellicle film 10. The pellicle film 10 is the pellicle film 10 illustrated in FIG. 1. The pellicle film 10 is formed in a rectangular shape and has a first pellicle film surface 11 that faces the supporting surface 33 of the support 30 and a second pellicle film surface 12 on the side opposite to the first pellicle film surface 11. A peripheral portion 13 of the pellicle film 10 is fixed to a portion of the supporting surface 33 of the frame 31, so that the pellicle film 10 covers the opening 32 of the support 30.

The above-described pellicle film according to the exemplary embodiment is used as the pellicle film 10. Examples of the material of the support 30 include resin materials (such as polyethylene), metal materials (such as aluminum, aluminum alloys, magnesium alloys, stainless steel, and titanium), ceramic materials (such as SiC), and fiber-reinforced plastic materials (such as carbon fiber-reinforced plastics).

An example of the pellicle according to the exemplary embodiment has been described above with reference to FIGS. 3 and 4. The pellicle according to the exemplary embodiment is not limited thereto. The pellicle according to the exemplary embodiment may employ any of various forms as long as the advantages of the pellicle including the above-described pellicle film according to the exemplary embodiment are obtained. The shapes, dimensions, etc., of portions of the members constituting the pellicle according to the exemplary embodiment can be determined according to, for example, the dimensions of a photomask (not illustrated) for which the pellicle according to the exemplary embodiment is used.

For example, the pellicle film 10 and the support 30 of the pellicle 100 illustrated in FIGS. 3 and 4 are each formed in a rectangular shape. The pellicle according to the exemplary embodiment is not limited thereto and may be formed in any desired shape such as a circular, elliptical, or polygonal shape.

For example, in the pellicle 100 illustrated in FIGS. 3 and 4, the peripheral portion 13 of the pellicle film 10 is fixed to a portion of the supporting surface 33 of the support 30. The pellicle 100 is not limited thereto, and the peripheral portion 13 of the pellicle film 10 may be fixed to the entire surface of the supporting surface 33 of the support 30.

Alternatively, for example, in FIGS. 3 and 4, the pellicle film 10 and the support 30 may be fixed together by providing a bonding layer (not illustrated). The bonding layer is a layer provided according to need. Examples of materials constituting the bonding layer that may be used include, but are not particularly limited to, various adhesives such as an acrylic resin, an epoxy resin, a silicone resin, a polyimide resin, and a fluororesin; and carbon nanotubes.

### Method for Producing Pellicle

An example of a preferred method for producing a pellicle according to the exemplary embodiment includes a step of preparing a pellicle film according to the exemplary embodiment, a step of preparing a support that has a frame and an opening surrounded by the frame and that supports the pellicle film, and a step of providing the pellicle film on the support such that the pellicle film covers the opening and is supported by a supporting surface of the frame. The production method may optionally include a step of providing a bonding layer on at least a portion of the supporting surface of the frame.

The step of preparing a pellicle film according to the exemplary embodiment includes preparing the pellicle film according to the exemplary embodiment described above. The step of preparing a support includes preparing a support formed in a desired shape by a publicly known method using the foregoing material constituting the support. The step of providing the pellicle film includes disposing the pellicle film by a publicly known method such that the pellicle film covers the opening and is supported by the supporting surface of the frame. When a bonding layer is provided on at least a portion of the supporting surface of the frame, the pellicle film is disposed so as to be supported by the supporting surface of the frame with the bonding layer therebetween. When any adhesive is used for the bonding layer, the step of providing a bonding layer includes applying an adhesive to the supporting surface to provide the bonding layer including the adhesive. When carbon nanotubes are used as the bonding layer, the step of providing a bonding layer includes, for example, applying a dispersion liquid of carbon nanotubes to the supporting surface, and drying the dispersion liquid to provide the bonding layer including the carbon nanotubes.

The pellicle according to the exemplary embodiment is used, for example, by being disposed above a photomask to be spaced apart from the photomask such that the first pellicle film surface faces the photomask. Use of the pellicle according to the exemplary embodiment suppresses adhesion of foreign matter to the photomask. Since the pellicle according to the exemplary embodiment includes the above-described pellicle film according to the exemplary embodiment, variation in EUV transparency is reduced, while high transparency to EUV is ensured. Furthermore, since the pellicle film according to the exemplary embodiment has a small amount of deformation and has good mechanical strength, for example, damage to the pellicle during arrangement and transportation is suppressed.

The invention is not limited to the above exemplary embodiments, and any of modifications, improvements, and the like are included in the invention as long as the objects of the invention can be achieved.

### EXAMPLES

The invention will be more specifically described below by way of Examples. However, the invention is not limited to these Examples.

### Example 1

### Preparation of Pellicle Film

Carbon nanotubes (hereinafter referred to as CNTs) having a diameter in a range from 0.2 nm to 50 nm and a length in a range from 1 μm to 250 μm were prepared as CNTs. The prepared CNTs were weighed such that the concentration in a first dispersion liquid of CNTs before dilution was 0.02% by mass. A surfactant serving as a dispersing agent was weighed such that the concentration in the first dispersion liquid of CNTs before dilution was 0.2% by mass. The weighed CNTs and the weighed surfactant were placed in water, and the CNTs were dispersed in water using a wet pulverization and dispersion device. As for dispersion conditions, the pressure was 70 MPa, and the number of times of treatment was three. Subsequently, dilution was performed such that the concentration of CNTs was 1 ppm to prepare the first dispersion liquid of CNTs. Next, the first dispersion liquid of

CNTs was collected such that, as the amount of CNTs included in the pellicle film, the mass of CNTs (denoted by Amount of CNTs in Table 1) was the numerical value shown in Table 1.

Subsequently, the first dispersion liquid of CNTs was subjected to centrifugal separation with a centrifugal separator under the conditions of a relative centrifugal acceleration of 100 kG and a treatment time of two hours to separate aggregates of CNTs. After the centrifugal separation, the supernatant was collected. This supernatant was used as a second dispersion liquid of CNTs. Subsequently, the second dispersion liquid of CNTs was filtered through a membrane filter to form a mat-shaped film product of CNTs on the membrane filter. The mat-shaped film product of CNTs was then peeled off from the membrane filter. The film product of

CNTs was heat-treated at 650 degrees C. for 30 minutes to prepare a pellicle film including CNTs. The pellicle film was a free-standing film.

### Evaluation of Pellicle Film

### Measurement of Visible Light Transmittance

A transmittance map of a pellicle film was prepared from the obtained pellicle film using the visible light transmittance measuring device 20 illustrated in FIGS. 2A, 2B, and 2C in accordance with step (S1) to step (S7) described above. The average value of the visible light transmittance was calculated by the numerical formula (Numerical Formula 1) based on the prepared transmittance map of the pellicle film. A mirrorless camera (“EOS R5”, manufactured by Canon Inc.) was used as an image-capturing device used in the procedure of step (S1) to step (S7) described above. The standard deviation of the visible light transmittance and the coefficient of variation of the visible light transmittance were determined from the average value of the visible light transmittance. The images acquired in steps (S4), (S5), and (S6) described above are images that have an area of 14,300 mm² and are composed of 700,000 pixels. In Table 1, the average value is denoted by AVE, the standard deviation is denoted by SD, and the coefficient of variation is denoted by CV.

### Amount of Deformation of Pellicle Film

The amount of deformation of the pellicle film was measured using a measuring device including a chamber having an opening that was partially open, a pressure sensor disposed inside the chamber, a holder configured to hold a sample in the opening of the chamber, and a laser displacement meter. The pellicle film obtained in each example was held in the holder, nitrogen gas was caused to flow into the chamber at a pressure of 2 Pa to deform the pellicle film held in the holder in the chamber, and the amount of deformation of the pellicle film at this time was measured with the laser displacement meter.

### Examples 2 and 3

Pellicle films of Examples were each prepared as in Example 1 except that the mass of CNTs included in the pellicle film was changed as described in Table 1, and the pellicle films were evaluated.

### Comparative Examples 1 and 2

Pellicle films of Comparative Examples 1 and 2 were each prepared as in Example 1 except that the mass of CNTs included in the pellicle film was changed as described in Table 1 and the centrifugal separation was not performed, and the pellicle films were evaluated.

TABLE 1

| | Amount of | Amount of | Visible light transmittance | | |
|---|---|---|---|---|---|
| | CNTs | deformation | AVE | SD | CV |
| | (μg/cm²) | (mm) | (%) | (%) | (—) |
| Example 1 | 1.024 | 2.864 | 81.42 | 0.516 | 0.634 |
| Example 2 | 0.9730 | 2.860 | 82.27 | 0.536 | 0.651 |
| Example 3 | 1.018 | 3.044 | 81.53 | 0.554 | 0.679 |
| Comparative | 0.9622 | 3.121 | 82.45 | 0.564 | 0.685 |
| Example 1 | | | | | |
| Comparative | 1.044 | 3.054 | 81.11 | 0.598 | 0.737 |
| Example 2 | | | | | |

The above results show that the pellicle films of Examples having a visible light transmittance in a range from 60% to 85%, the visible light transmittance being calculated by the numerical formula (Numerical Formula 1), and a standard deviation of the visible light transmittance of 0.56% or less have small standard deviations and small coefficients of variation of the visible light transmittances and also have small amounts of deformation of the pellicle films, even when the average values of the visible light transmittance are substantially the same as those of the pellicle films of Comparative Examples. Furthermore, the pellicle films of Examples have high visible light transmittances and small standard deviations and small coefficients of variation of the visible light transmittances, although the mass of CNTs included in the pellicle films are relatively large. In addition, the pellicle films of Examples have improved mechanical strength because the amounts of deformation are also smaller than those of the pellicle films of Comparative Examples. Thus, the results obtained in each of the pellicle films of Examples show that the mechanical strength is improved, while ensuring that the pellicle film has a large CNT content and has an excellent light transmittance, and variation in the light transmittance is reduced.

Accordingly, the exemplary embodiment provides a pellicle film in which variation in EUV transparency is reduced and which has a small amount of deformation, while high transparency to EUV is ensured, and a pellicle including the pellicle film. The exemplary embodiment provides a method for measuring a visible light transmittance (average value) and a standard deviation of the visible light transmittance of a pellicle film, which can be used as an indicator of essential variation in EUV transparency of the pellicle film. The exemplary embodiment further provides a method for measuring a coefficient of variation of the visible light transmittance of a pellicle film, which can be used as an indicator of essential variation in EUV transparency of the pellicle film.

What is claimed is:

1. A pellicle film having a porous structure,
wherein the pellicle film comprises carbon nanotubes,
the pellicle film has a first pellicle film surface and a second pellicle film surface on a side opposite to the first pellicle film surface,
a visible light transmittance is in a range from 60% to 85%, the visible light transmittance being calculated by a numerical formula (Numerical Formula 1) below based on:
(1) an image of the pellicle film in a light-transmitting state, the image being composed of 700,000 pixels or more in an area of 14,300 mm² and captured on a side of the first pellicle film surface in a state where a side of the second pellicle film surface is placed on an image-capturing position and white light with a wavelength in a range from 400 nm to 750 nm is applied from the side of the second pellicle film surface,
(2) an image of the image-capturing position in a bright state, the image being composed of the same number of pixels or more as that in (1) above in the area and obtained by imaging the image-capturing position not including the pellicle film in a state where the white light is applied, and
(3) an image of the image-capturing position in a dark state, the image being composed of the same number of pixels or more as that in (1) above in the area and obtained by imaging the image-capturing position not including the pellicle film in a light-shielded state, and
a standard deviation of the visible light transmittance is 0.56% or less,
$$T = \{ ( Tp - Td ) / ( Tb - Td ) \} \times 100 \qquad ( Numerical Formula 1 )$$
in the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.

2. The pellicle film according to claim 1,
wherein a coefficient of variation of the visible light transmittance is 0.68 or less.

3. The pellicle film according to claim 1,
wherein the carbon nanotubes have a length in a range from 0.1 μm to 1,000 μm.

4. The pellicle film according to claim 1,
wherein the carbon nanotubes have a cross-sectional diameter in a range from 0.2 nm to 50 nm.

5. The pellicle film according to claim 1,
being a free-standing pellicle film.

6. A pellicle comprising:
the pellicle film according to claim 1; and
a support that has a frame and an opening surrounded by the frame and that supports the pellicle film.

7. A method for measuring a visible light transmittance and a standard deviation of the visible light transmittance of a pellicle film having a porous structure, the method comprising:
preparing a pellicle film including carbon nanotubes and having a first pellicle film surface and a second pellicle film surface on a side opposite to the first pellicle film surface;
placing the prepared pellicle film on an image-capturing position such that the second pellicle film surface faces the image-capturing position;
applying white light with a wavelength in a range from 400 nm to 750 nm from a side of the second pellicle film surface of the placed pellicle film to transmit the white light through the pellicle film;
capturing an image with an image-capturing device, in a state where the white light is applied, on a side of the first pellicle film surface to which the white light is not applied, thereby acquiring the image of the pellicle film in a light-transmitting state, the image being composed of 700,000 pixels or more in an area of 14,300 mm²;
capturing an image of the image-capturing position not including the pellicle film in a state where the white light is applied, thereby acquiring the image of the image-capturing position in a bright state, the image being composed of 700,000 pixels or more in an area of 14,300 mm²;
capturing an image of the image-capturing position not including the pellicle film in a light-shielded state where the white light is not applied, thereby acquiring the image of the image-capturing position in a dark state, the image being composed of 700,000 pixels or more in an area of 14,300 mm²; and
calculating a visible light transmittance and a standard deviation of the visible light transmittance of the pellicle film based on the image of the pellicle film in the light-transmitting state, the image of the image-capturing position in the bright state, and the image of the image-capturing position in the dark state,
wherein the visible light transmittance of the pellicle film is determined by a numerical formula (Numerical Formula 1) below,
$$T = \{ ( Tp - Td ) / ( Tb - Td ) \} \times 100 \qquad ( Numerical Formula 1 )$$
in the numerical formula (Numerical Formula 1), T represents a visible light transmittance of the pellicle film, Tp represents a pixel value indicating that the white light is transmitted in the image of the pellicle film in the light-transmitting state, Tb represents a pixel value indicating that the white light is transmitted in the image of the image-capturing position in the bright state, and Td represents a pixel value determined when the white light is not applied in the image of the image-capturing position in the dark state.
